(19) United States
(12) Patent Application Publication
(10) Pub. No.: US 2025/0038154 A1
(43) Pub. Date: Jan. 30, 2025

(54) Test Apparatus For Flip-Chip Micro-Light Emitting Diode (LED) Devices

(71) Applicant: Lumileds LLC, San Jose, CA (US)

(72) Inventors: Wee-Hong Ng, Singapore (SG); Yeow Meng Teo, Singapore (SG); Wali Zhang, Singapore (SG); Srinivasa Banna, San Jose, CA (US)

(73) Assignee: Lumileds LLC, San Jose, CA (US)

(21) Appl. No.: 18/717,511

(22) PCT Filed: Dec. 5, 2022
(86) PCT No.: PCT/US2022/080903

§ 371 Date: Jun. 7, 2024

Related U.S. Application Data
(60) Provisional application No. 63/288,139, filed on Dec. 10, 2021.

(51) Int. Cl. H01L 25/075; H01L 21/66; H01L 33/62

(52) U.S. Cl. CPC H01L 25/0753; H01L 22/14; H01L 33/62; H01L 2933/0066

(57) ABSTRACT

Micro-light emitting diode (uLED) devices comprise: a plurality of micro-light emitting diodes (uLEDs), each of the uLEDs comprising: a pixel; an N-contact in contact with the pixel and having an N-contact top surface; a P-contact in contact with the pixel and having a P-contact top surface; an N-contact test pad on the N-contact top surface and having an N-contact test pad surface; and a P-contact test pad on the P-contact top surface and having a P-contact test pad surface; and a primary release layer positioned between all of the N-contacts and P-contacts of the uLEDs. Test apparatus and methods of making and testing the same are also provided.

### TECHNICAL FIELD

Embodiments of the disclosure generally relate to micro-light emitting diode (uLED) devices including micro-light emitting diodes (uLEDs) and methods of manufacturing the same. More particularly, embodiments are directed to uLED devices that are testable, and testing apparatus for testing arrays of the same. The uLED devices comprise: N-contact test pads and P-contact test pads attached to respective N-contacts and P-contacts of each uLED, in conjunction with a release layer. Testing apparatuses comprise: an N-contact test pad template in contact with an N-contact testing bus and a P-contact test pad template in contact with a P-contact testing bus, in conjunction with a release layer.

### BACKGROUND

Semiconductor light-emitting devices or optical power emitting devices (such as devices that emit ultraviolet (UV) or infrared (IR) optical power), including light emitting diodes, resonant cavity light emitting diodes, vertical cavity laser diodes, and edge emitting lasers, are among the most efficient light sources currently available. Due to their compact size and lower power requirements, for example, semiconductor light or optical power emitting devices (referred to herein as LEDs for simplicity) are attractive candidates for light sources, such as camera flashes, for hand-held battery-powered devices, such as cameras and cell phones. They may also be used, for example, for other applications, such as for automotive lighting, torch for video, and general illumination, such as home, shop, office and studio lighting, theater/stage lighting and architectural lighting.

High-intensity/brightness light emitting devices capable of operation across the visible spectrum include Group III-V semiconductors, particularly binary, ternary, and quaternary alloys of gallium, aluminum, indium, and nitrogen, also referred to as III-nitride materials. Typically, Ill-nitride light emitting devices are fabricated by epitaxially growing a stack of semiconductor layers of different compositions and dopant concentrations on a growth substrate such as a sapphire, silicon carbide, Ill-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region.

Various emerging display applications, including wearable devices, head-mounted, and large-area displays require miniaturized chips composed of arrays of microLEDs (μLEDs or uLEDs) with a high density having a lateral dimension down to less than 100 μm×100 μm. MicroLEDs (uLEDs) typically have dimensions of about 50 μm in diameter or width and smaller that are used to in the manufacture of color displays by aligning in close proximity microLEDs comprising red, blue and green wavelengths. Present design architecture of a standalone microLED pixel does not allow a permanent test pad for electrical testing due to its micro-sizes.

There is a need to electrically test microLED pixels without increasing the pixel size and/or damaging the pixel.

### SUMMARY

Provided herein are micro-light emitting diode (uLED) devices including micro-light emitting diodes (uLEDs) and methods of manufacturing the same.

In an aspect, a micro-light emitting diode (uLED) device comprises: a plurality of micro-light emitting diodes (uLEDs), each of the uLEDs comprising: a pixel; an N-contact in contact with the pixel and having an N-contact top surface; a P-contact in contact with the pixel and having a P-contact top surface; an N-contact test pad on the N-contact top surface and having an N-contact test pad surface; and a P-contact test pad on the P-contact top surface and having a P-contact test pad surface; and a primary release layer positioned between all of the N-contacts and P-contacts of the uLEDs.

Another aspect is a method of manufacturing a micro-light emitting diode (uLED) device, the method comprising: depositing a primary release material on an array of micro-light emitting diodes (uLEDs), each uLED comprising: a pixel, an N-contact, and a P-contact, each of the N-contact and the P-contact in contact with each of the pixels; etching the primary release material to expose each of the N-contacts and the P-contacts, thereby forming a primary release layer; and preparing an N-contact test pad on each of the N-contacts and a P-contact test pad on each of the P-contacts.

A further aspect is a testing apparatus for an array of micro-light emitting diode (uLEDs), the testing device comprising: a primary release layer positioned on the array of uLEDs; an N-contact test pad template in contact with N-contacts of the uLEDs and an N-contact testing bus; and a P-contact test pad template in contact with P-contacts of the uLEDs and a P-contact testing bus.

In an aspect, a method of manufacturing a light source comprises: testing an array of micro-light emitting diode (uLEDs) with the testing apparatus according any aspect herein; and assembling a light source comprising uLEDs identified as acceptable upon the testing.

Another aspect is a method of manufacturing a testing apparatus for testing an array of micro-light emitting diode (uLEDs), the method comprising: depositing a primary release material on the array of uLEDs, each uLED comprising: a pixel, an N-contact, and a P-contact, each of the N-contact and the P-contact in contact with each of the pixels; etching the primary release material to expose each of the N-contacts and the P-contacts, thereby forming a primary release layer; and preparing an N-contact test pad template on each of the N-contacts, an N-contact testing bus in communication with the N-contact test pad template, a P-contact test pad template on each of the P-contacts, and a P-contact testing bus in communication with the P-contact test pad template.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements. The figures herein are not to scale.

FIG. 1 is a schematic view illustrating in cross-section a micro-light emitting diode (uLED) device according to one or more embodiments;

FIG. 2 is a schematic top view of the uLED device of FIG. 1;

FIG. 3 is a schematic view illustrating in cross-section a micro-light emitting diode (uLED) device according to one or more embodiments;

FIG. 4 is a schematic top view of the uLED device of FIG. 3;

FIG. 5 provides a process flow diagram for manufacture of a light emitting diode (LED) device according to one or more embodiments;

FIGS. 6A-6D are schematic views illustrating in cross-section an array of micro-light emitting diode (uLED) devices at different stages according to one or more embodiments;

FIG. 7 provides a process flow diagram for manufacture of uLED device after electrical testing according to one or more embodiments;

FIG. 8 is a cross-sectional view of a uLED device in accordance with one or more embodiments;

FIG. 9 is a schematic top view of a uLED test apparatus according to one or more embodiments;

FIG. 10 is a schematic top view of a uLED test apparatus according to one or more embodiments;

FIG. 11 is a schematic side view of an optical screening set-up including an exemplary uLED test apparatus and optical sensor according to one or more embodiments;

FIG. 12 provides a process flow diagram for testing of a uLED device according to one or more embodiments;

FIG. 13 illustrates a top view of an exemplary display device according to one or more embodiments; and

FIG. 14 schematically illustrates an exemplary display system comprising uLED devices according to embodiments herein.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Reference to LED refers to a light emitting diode that emits light when current flows through it. In one or more embodiments, the LEDs herein have one or more characteristic dimensions (e.g., height, width, depth, thickness, etc. dimensions) in a range of greater than or equal to 75 micrometers to less than or equal to 300 micrometers. In one or embodiments, one or more dimensions of height, width, depth, thickness have values in a range of 100 to 300 micrometers. Reference herein to micrometers allows for variation of ±1-5%. In a preferred embodiment, one or more dimensions of height, width, depth, thickness have values of 200 micrometers ±1-5%. In some instances, the LEDs are referred to as micro-LEDs (uLEDs or uLEDs), referring to a light emitting diode having one or more characteristic dimensions (e.g., height, width, depth, thickness, etc. dimensions) on the order of micrometers or tens of micrometers. In one or embodiments, one or more dimensions of height, width, depth, thickness have values in a range of 1 to less than 75 micrometers, for example from 1 to 50 micrometers, or from 1 to 25 micrometers. Overall, in one or more embodiments, the LEDs herein may have a characteristic dimension ranging from 1 micrometers to 300 micrometers, and all values and sub-ranges therebetween.

Methods of depositing materials, layers, and thin films include but are not limited to: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Methods of forming or growing semiconductor layers including N-type layer, active region, and P-type layer are formed according to methods known in the art. In one or more embodiments, the semiconductor layers are formed by epitaxial (EPI) growth. The semiconductor layers according to one or more embodiments comprise epitaxial layers, III-nitride layers, or epitaxial III-nitride layers. In one or more embodiments, the semiconductor layers comprise a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In one or more embodiments, the semiconductor layers have a combined thickness in a range of from about 2 μm to about 10 μm, and all values and subranges therebetween.

In order to conduct electrical testing of devices including pixels or LEDs, there should be adequate access to permanent contacts of the device and adequate surface area to accommodate additional electrical contact points of a test apparatus. Due to decreasing sizes of LEDs, with particular regard to micro-LEDs (uLEDs), there are limitations to the ability to electrically test uLEDs due to inadequate access to permanent contacts of the device and inadequate surface area to accommodate additional electrical contact points of a test apparatus. With uLEDs, sizing of permanent N-contacts and P-contacts, which are used to light up the uLED during testing, is not adequate for electrical testing without the risk of damaging the permanent contacts.

Due to this limited access, uLED manufacturers typically either skip the electrical testing of uLED pixels at the wafer level, and test at the finished product level as a lagging indicator, which increases the cost of production; or probe directly on the pixel without electrical pads, hence risking damages to the live pixel.

Other methods like photoluminescence (PL) and contactless electroluminescence (EL) are often used to screen off defects on the uLED pixel. Such methods, however, do have their limitations in measuring the absolute electrical properties such as Vf, Vflow, Vr and etc.

Advantageously, devices and techniques herein offer temporary test pads as contacts to an electrical probe, which permits measurement of absolute electrical properties. Accordingly, uLED pixels may be tested with the use of temporary electrical test pads, without increasing the pixel size and/or damaging the live pixel.

Devices and methods herein create an architecture that form temporary, e.g., removable, electrical test pads for electrical testing. In cooperation with the architecture, a layout change can be applied to enable mass volume uLED electrical testing and optical screening. The temporary test pads can be removed subsequently for downstream processes with negligible to no impact on form, fit, or function of the final uLED device products.

Suitable applications for the technology herein include but are not limited to very high brightness microLED requirements generally found in advanced automotive ADB, or high resolution high brightness displays, apart from the host of other flash, display and illumination applications that can be achieved with LEDs, including uLEDs. Architectures suitable for the technology herein include flip-chip devices where P- and N-contacts are formed on a same side of pixel of the uLED.

In general, a coating of a release layer on top of manufactured uLED pixel(s) is applied. The release layer covers topography of the pixel(s). The release layer is subsequently pattered to form open area above the N-contact and P-contact of each pixel(s). Thereafter, contact test pads (e.g, N-contact and P-contact test pads) are prepared on top of the release layer by metallization. In one or more embodiments, the metallization can be patterned by means of liftoff methodology. Alternatively, the metallization can be patterned by etching. The contact test pads are in electrical communication with the N- and P-contacts of the uLED pixel(s) as contact points for electrical testing. This structure of uLED pixel, release layer, and contact test pads is ready for electrical testing.

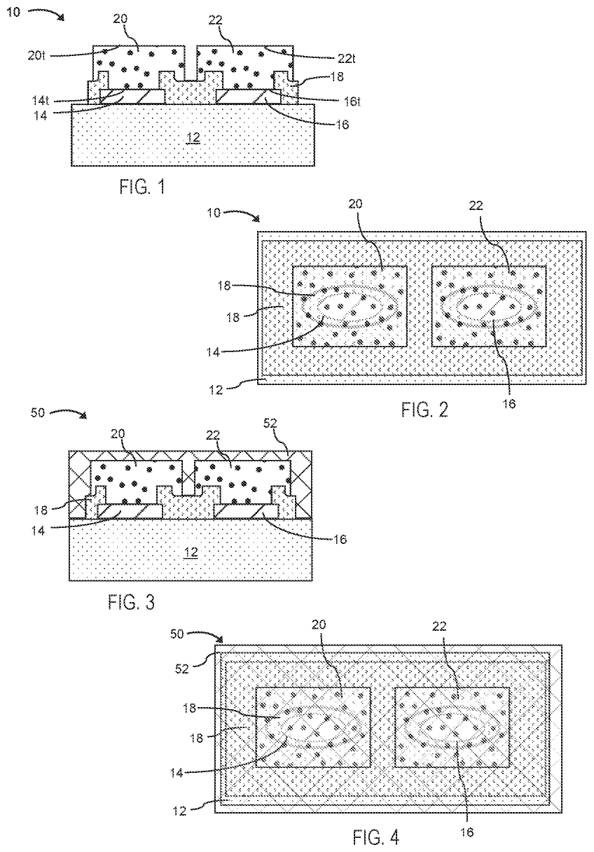

FIG. 1 is a schematic view illustrating in cross-section a micro-light emitting diode (uLED) device according to one or more embodiments, and FIG. 2 is a schematic top view of the uLED device of FIG. 1. FIG. 3 is a schematic view illustrating in cross-section another uLED device according to one or more embodiments, and FIG. 4 is a schematic top view of the uLED device of FIG. 3.

With reference to FIGS. 1-4, the uLED devices 10 and 50 both comprises a pixel 12, which is a stack of semiconductor layers including an active region; N-contact 14 and P-contact 16, which are in electrical communication, e.g., in contact with, the pixel; a first or primary release layer 18 between N-contact 14 and the P-contact 16; and contact test pads: an N-contact test pad 20 on an N-contact top surface 14t, and a P-contact test pad 22 on the P-contact top surface 16t. The N-contact test pad 20 has an N-contact test pad surface 20t, and the P-contact test pad 22 has a P-contact test pad surface 22t.

In one or more embodiments, a first surface area of the N-contact test pad surface 20t is larger than a second surface area of the N-contact top surface 14t. In one or more embodiments, a third surface area of the P-contact test pad surface 22t is larger than a fourth surface area of the P-contact top surface 16t. In one or more embodiments, the first surface area of the N-contact test pad surface 20t is larger than the second surface area of the N-contact top surface 14t, and the third surface area of the P-contact test pad surface 22t is larger than a fourth surface area of the P-contact top surface 16t.

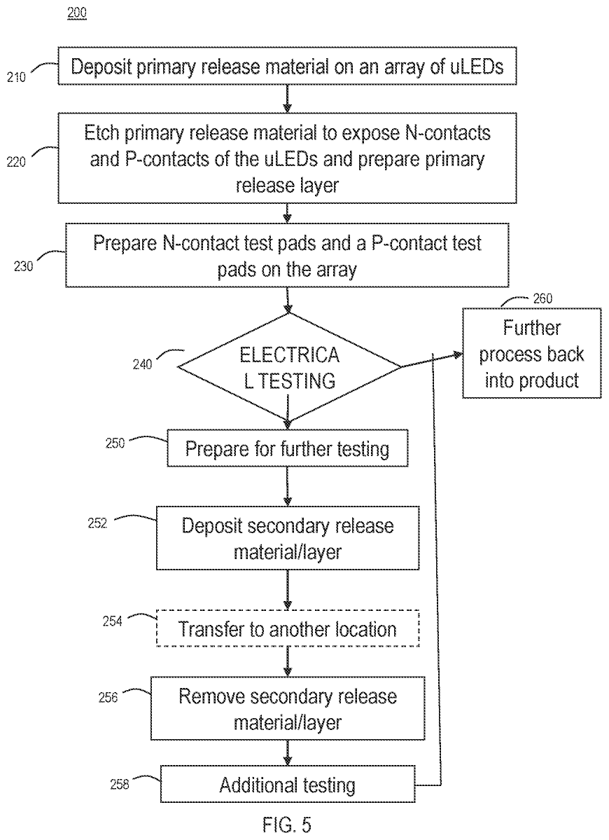

With reference to FIGS. 4-5, the structure further comprises a secondary release layer 52, which covers the N-contact test pad 20 and the P-contact test pad 22 on exposed surfaces. The secondary release layer 52 also covers any exposed areas of the release layer 18 and the pixel 12. The secondary release layer 52 can be applied to a structure of FIGS. 1-2 to protect the contact test pads (the N-contact test pad 20 the P-contact test pad 22) during packaging and or shipping.

In embodiments, the primary release layer 18 and/or the secondary release layer 52 independently comprise a photoresist material. In one or more embodiments, the photoresist material comprises polydimethylglutarimide (PMGI) and/or a cyclopentanone-based polymer. In one or more embodiments, release layer material or film is coated using spin coating. In one or more embodiments, a thickness range of the primary release layer 18 is less than or equal to 3 micrometers (μm).

In one or more embodiments, the N-contact and the P-contact comprise one or more of: aluminum (Al), nickel (Ni), titanium (Ti), gold (Au), platinum (Pt), and palladium (Pd). In one or more embodiments, a capping, protective layer is included on the N-contact and the P-contact. In one or more embodiments, the capping layer comprises Au, Pd, or Pt. The capping layer can be greater than or equal to 2000 Å thick and also acting as an etch stop layer (if applicable).

In one or more embodiments, the N-contact test pad and the P-contact test pad comprises one or more of: copper (Cu), aluminum (Al), nickel (Ni), titanium (Ti), titanium-tungsten (TiW), silver (Ag), gold (Au), platinum (Pt), and palladium (Pd).

In some embodiments, the pixel is affixed to and supported by a device substrate. In one or more embodiments, the device substrate comprises: a material selected from the group consisting of: a sapphire, silicon carbide, and III-nitride.

FIG. 5 provides a process flow diagram 200 for manufacture of a light emitting diode (LED) device according to one or more embodiments. A manufactured source of uLEDs may be in the form of a monolithic array of uLEDs where a plurality of uLEDs are integral to a device body or substrate. Other uLEDs may be singulated and affixed to a submount or other device as an array. Upon manufacture of uLEDs, it is desirable to test the pixels to avoid yield loss and rework in subsequent processing steps.

At operation 210, a primary release material is deposited onto an array of uLEDs, which include exposed N-contacts and P-contacts. At operation 220, the primary release material is etched to re-expose the N-contacts and P-contacts of the uLEDs. Upon completion of the etching, a primary release layer is prepared.

At operation 230, N-contact test pads and a P-contact test pads are prepared on the array from a test pad material. In some embodiments, preparing the N-contact test pads and the P-contact test pads includes: depositing the test pad material on the array; and patterning the test pad material. In other embodiments, preparing the N-contact test pads and the P-contact test pads is a liftoff-type process where a mask material is deposited in a pattern on the array, then the test pad material is deposited, and then the mask material is removed. In one or more embodiments, the test pad material is deposited by an evaporation or sputtering process or a combination of both to a thickness of less than or equal to 2 micrometers.

The test pad material may comprise one or more of: copper (Cu), aluminum (Al), nickel (Ni), titanium (Ti), titanium-tungsten (TiW), silver (Ag), gold (Au), platinum (Pt), and palladium (Pd). The test pads have properties of forming ohmic contact with the uLED N-contact and the P-contact, and also positive and negative probe pins. This is deposited through either an evaporation or sputtering process, or a combination of both. The thickness range of the test pad metal stack will typically be less than or equal to 2 micrometers. The option of test pad material desirable is chemically “unstable” in that it can be removed chemically without affecting an N-contact and P-contact or its capping layer. In one or more embodiments, the text pad material is Al or Cu.

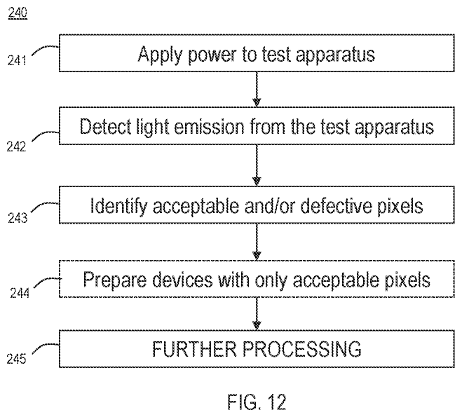

At operation 240, electrical testing of the structure is conducted. This operation is discussed in more detail with respect to the testing process flow diagram of FIG. 12.

After electrical testing at operation 240, arrays can be prepared for further testing at operation 250, or they can be further processed back into a final product at operation 260.

With regard to preparing for further testing at operation 250, a secondary release material is deposited on the array at operation 252 to form a secondary release layer, resulting in uLED devices according to FIGS. 3-4. The secondary release material is not patterned. Optionally, such devices are transferred to another location at operation 254, or otherwise packaged and shipped, for example to a customer or distributor.

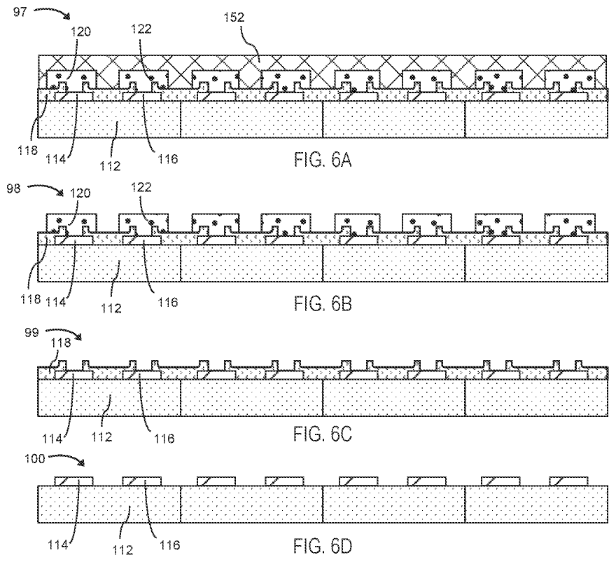

Turning to FIG. 6A, operations 252 and 254 relate to an array 97 of a plurality of uLEDs 112, each uLED 112 having a N-contact 114 and a P-contact 116, includes a primary or first release layer 118 on the pixels 112 and a portion of the N-contacts 114 and the P-contacts 116. The pixels 112 are isolated from each other. In one or more embodiments, a light-blocking material is between all of the pixels 112. In one or more embodiments, dielectric and/or reflective materials are between all of the pixels 112. N-contact test pads 120 are on respective top surfaces of the N-contacts 114, and P-contact test pads 122 are on respective top surfaces of the P-contacts 116. A secondary or second release layer 152 is shown in this embodiment, which protects the N-contact test pads 120 and the P-contact test pads 122. The array 97 including the secondary release layer 152 could be packaged and/or shipped for the purposes of re-testing at another location.

Thereafter, at operation 256, the secondary release layer is removed to expose the contact test pads. Removal of the secondary release layer is achieved by techniques generally used to remove resist during LED processing. For example, removal if the secondary release layer can be done with chemical wet etch or dry etch, where chemistry and process are selected based on its compatibility with and selectivity to the components of the uLED pixel.

In FIG. 6B, an array 98 of the plurality of uLEDs 112, each uLED 112 having the N-contact 114 and the P-contact 116, and including the primary release layer 118 on the pixels 112 and a portion of the N-contacts 114 and the P-contacts 116. The N-contact test pads 120 remain on respective top surfaces of the N-contacts 114, and the P-contact test pads 122 remain on respective top surfaces of the P-contacts 116 relative to FIG. 6A. The secondary release layer 152 of FIG. 6A is not present. The array 98 could result from the operation 256 or it could be the structure that was electrically tested in operation 240.

At operation 258, any additional testing is conducted.

After electrical testing, the arrays could also be shipped to another location, for example a customer or distributor, without a secondary release layer, and subjected to further testing as-needed.

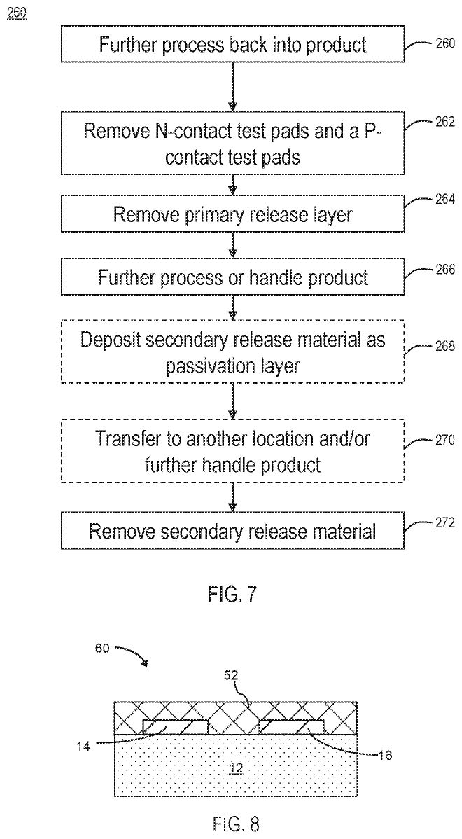

FIGS. 6B-6D and FIG. 7 relate to a further process to return the structure into a product according to operation 260 of FIG. 5. FIGS. 6B-6D are schematic views illustrating in cross-section an array of micro-light emitting diode (uLED) devices at different stages after electrical testing according to one or more embodiments. FIG. 7 provides a process flow diagram for manufacture of uLED device after electrical testing according to one or more embodiments.

The array 98 of FIG. 6B, including the N-contact test pads 120 and the P-contact test pads 122 is processed at operation 262 of the FIG. 7 process flow diagram for their removal. In one or more embodiments, techniques for removing the contact test pads include chemical wet etch exposing the N-contact, P-contact, and the primary release layer. The etch of the contact test pads etch can be an anisotropic etch of the metals with high etch selectivity relative to the N-contact, P-contact, and the primary release layer. As non-limiting example, a dilute sulfuric peroxide can be used to etch away a temporary test pad of Cu without any impact on a capping layer of Au, Pd, or Pt on the N- and P-contacts. As a non-limiting example, HF can be used to etch away a temporary test pad of Al without any impact on a capping layer of Au, Pd, or Pt.

The structure after operation 262 of FIG. 7 is shown in FIG. 6C, which is an array 99 comprising the plurality of uLEDs 112, each uLED 112 having the N-contact 114 and the P-contact 116, and including the primary release layer 118 on the pixels 112. The N-contact test pads 120 and the P-contact test pads 122 are removed relative to FIG. 6B.

At operation 264 of FIG. 7, the primary release layer 118 of FIG. 6C is removed. In one or more embodiments, techniques for removing the primary release layer include chemical wet etch or dry etch. Chemistry and process are based on compatibility with and selectivity to the exposed N-Contact and P-contact and uLED pixel. In one or more embodiments, residual release layer may remain without impacting performance of uLED pixels.

After operation 264, array of uLEDs are restored to their original form, fit, function as shown in FIG. 6D. The uLED array of FIG. 6D comprises the plurality of pixels 112, each having the N-contact 114 and the P-contact 116.

At operation 266, the array 100 can be further processed or handled.

Another optional opportunity to deposit a secondary release layer is at operation 268. This secondary release layer could serve as a passivation layer for any subsequent translation to another location or further handling of the product at operation 270. In FIG. 8, a cross-sectional view of a uLED device in accordance with one or more embodiments is shown, where uLED 60 comprises a pixel 12 including an N-contact 14 and a P-contact 16 and a passivation layer 52, e.g. secondary release layer, on the pixel 12, the N-contact 14, and the P-contact 16. This embodiment and/or an array of such uLEDs can be packaged and/or shipped.

Thereafter, the secondary release layer could be removed at operation 272, returning the uLEDs to their original form.

To ease large volume testing, a layout of the release layer and contact test pads can be modified to perform mass uLED pixels testing. For mass testing, contact test pads discussed above are collectively provided in a test pad template format. Generally, all N-contacts of the uLED pixels can be connected in parallel and routed to an N-contact testing bus while all P-contacts of the uLED pixels can be connected in parallel and routed to a P-contact testing bus for mass testing.

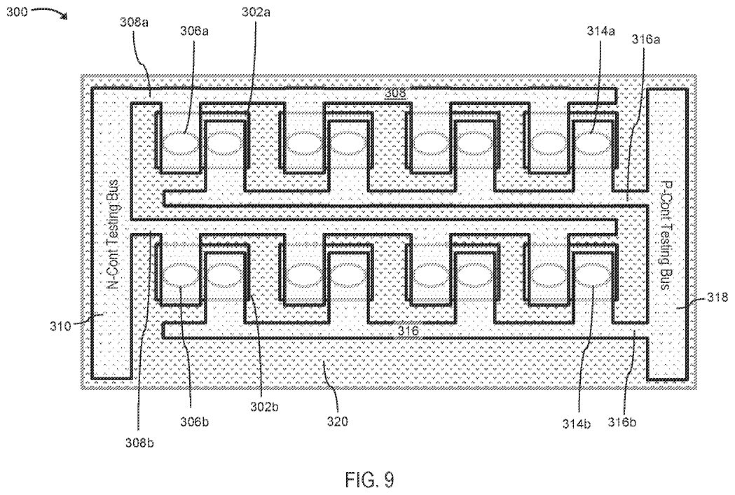

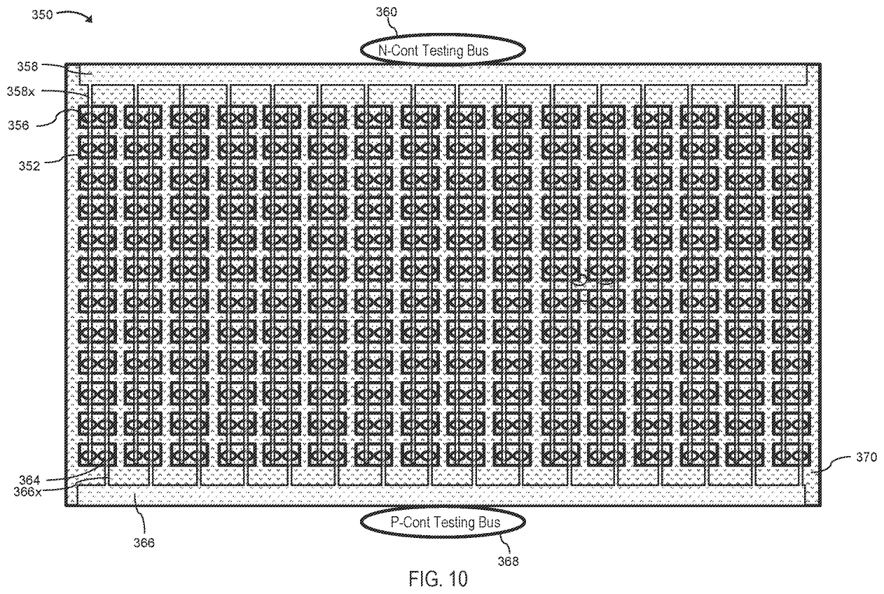

Turing to FIGS. 9-10, schematic top view of uLED test apparatuses according to one or more embodiments are provided. Sizes of the illustrated arrays are merely exemplary. It is understood that array sizes could be configured to include sizes that coordinate with manufacturing practices. In one or more embodiments, the test apparatuses herein are effective for testing greater than or equal to 10,000 uLEDs at a time, including greater than or equal to 100,000 uLEDs at a time, and greater than or equal to 500,000 uLEDs at a time. In one or more embodiments, the uLEDs are on an array support. In one or more embodiments, the array support is a complementary metal oxide semiconductor (CMOS) integrated circuit (IC) array. In one or more embodiments, the CMOS has metal interconnect bonding corresponding to the N- and P-contacts of the uLED array.

In FIG. 9, test apparatus 300 comprises a primary release layer 320 positioned on an array of uLEDs 302, which include uLEDs 302a in a first row of the array, and uLEDs 302b in a second row of the array. An N-contact test pad template 308 is in electrical communication, e.g., in contact, with N-contacts 306 of the uLEDs, including the N-contacts 306a of the first row and the N-contacts 306b of the second row, and an N-contact testing bus 310. A P-contact test pad template 316 is in electrical communication, e.g., in contact, with P-contacts 314 of the uLEDs, including the P-contacts 314a of the first row and the P-contacts 314b of the second row, and a P-contact testing bus 318. A first portion of the N-contact test pad template 308a connects the N-contacts 306a of the first row to the N-contact testing bus 310. A second portion of the N-contact test pad template 308b connects the N-contacts 306b of the second row to the N-contact testing bus 310. A first portion of the P-contact test pad template 316a connects the P-contacts 314a of the first row to the P-contact testing bus 318. A second portion of the P-contact test pad template 316b connects the P-contacts 314b of the second row to the P-contact testing bus 318. The N-contacts 306 of the uLEDs are connected in parallel with the N-contact testing bus 310. The P-contacts 314 of the uLEDs are connected in parallel with the P-contact testing bus 318. During testing, a negative probe pin would be applied to the N-contact testing bus 310 and a positive probe pin would be applied to the P-contact testing bus 318. In one or more embodiments, the array of uLEDs is on a device support, for example, a sapphire substrate.

In FIG. 10, test apparatus 350 comprises a primary release layer 370 positioned on an array of uLEDs 352. An N-contact test pad template 358 is in electrical communication, e.g., in contact, with N-contacts 356 of the uLEDs and an N-contact testing bus 360. For each column of uLEDs, a portion of the N-contact test pad template 358 connects all of the N-contacts. For example, a first portion of the N-contact test pad template 358x connects all of the N-contacts 356 of the first column of uLEDs. A P-contact test pad template 366 is in electrical communication, e.g., in contact, with P-contacts 364 and a P-contact testing bus 368. For each column of uLEDs, a portion of the P-contact test pad template 366 connects all of the P-contacts. For example, a first portion of the P-contact test pad template 366x connects all of the P-contacts 366 of the first column of uLEDs. The N-contacts 356 of the uLEDs are connected in parallel with the N-contact testing bus 350. The P-contacts 364 of the uLEDs are connected in parallel with the P-contact testing bus 368. During testing, a negative probe pin would be applied to the N-contact testing bus 360 and a positive probe pin would be applied to the P-contact testing bus 368. In one or more embodiments, the array of uLEDs is on a device support, for example, a sapphire substrate.

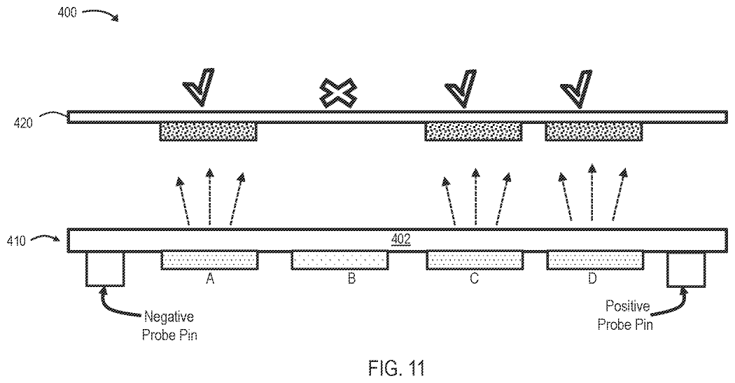

FIG. 11 is a schematic side view of an optical screening set-up 400 including an exemplary uLED test apparatus 410 according to any embodiment herein and optical sensor 420. For simplicity, the uLED pixels A, B, C, and D supported on a device substrate 402 (e.g., a substrate support) are illustrated but it is understood that the uLED test apparatus 410 includes temporary contact test pads and/or test pad templates for communication with the N-contacts and P-contacts of the uLEDs. The optical screening in embodiments can be done on an opposite side of the device, e.g., sapphire side. In this illustration, pixels A, C, and D are satisfactory in that they light-up upon application of current to the test apparatus 410. Pixel B is defective. At the optical sensor 420, there is detection of the light corresponding to the positions from A, C, and D is detected and no light at the position for pixel B. Generally, any pixels that are lit-up can be yielded with the use of optical pattern recognition software, and any dark pixels will be yielded off. A uLED map can be generated for subsequent pixel transfer process.

FIG. 12 provides a process flow diagram 240 for testing of a uLED device according to one or more embodiments. At operation 241, power is applied to the test apparatus. At operation 242, light emission is detect from the test apparatus. This may be done by an optical sensor. At operation 243, acceptable and/or defective pixels are identified. Optionally, a map of the pixels is generated.

Generally, pixels failing the test criteria set by user will be considered defective and are identified and/or mapped. These defective pixels can be reworked and/or rejected. Pixels meeting the test criteria set by user will be considered satisfactory/acceptable and will be identified and/or mapped for further processing.

At operation 244, devices with only acceptable pixels are prepared. In one or more embodiments, pick-and-place operations are conducted including only acceptable pixels. The pick-and-place operations can be done in-situ within the test apparatus (if tool's capability allows) or ex-situ in another pick-and-place tool.

At operation 245, optional further post-processing is performed. In one or more embodiments, further processing of acceptable pixels including formation of a passivation layer around a portion or the entirety of a LED or a uLED or the device as a whole. In one or more embodiments, the processed structure retains a substrate, is singulated, and is further processed. In one or more embodiments, the processed structure is flipped and affixed to a support, for example, a tape support, and the substrate is removed. Removal of the substrate is in accordance with methods known in the art including substrate laser liftoff. Upon removal of the substrate, singulated LEDs or uLEDs are created.

Further processing can include deposition of a down-converter material, e.g. layers of a phosphor material.

In some embodiments, LED devices herein are further processed to include optical elements such as lenses, metalenses, and/or pre-collimators. Optical elements can also or alternatively include apertures, filters, a Fresnel lens, a convex lens, a concave lens, or any other suitable optical element that affects the projected light from the light emitting array. Additionally, one or more of the optical elements can have one or more coatings, including UV blocking or anti-reflective coatings. In some embodiments, optics can be used to correct or minimize two- or three dimensional optical errors including pincushion distortion, barrel distortion, longitudinal chromatic aberration, spherical aberration, chromatic aberration, field curvature, astigmatism, or any other type of optical error. In some embodiments, optical elements can be used to magnify and/or correct images. Advantageously, in some embodiments magnification of display images allows the light emitting array to be physically smaller, of less weight, and require less power than larger displays. Additionally, magnification can increase a field of view of the displayed content allowing display presentation equals a user's normal field of view.

uLED Devices

Some uLED devices comprise single or singulated LEDs or pixels. Other devices comprise arrays and groups of LEDs or pixels.

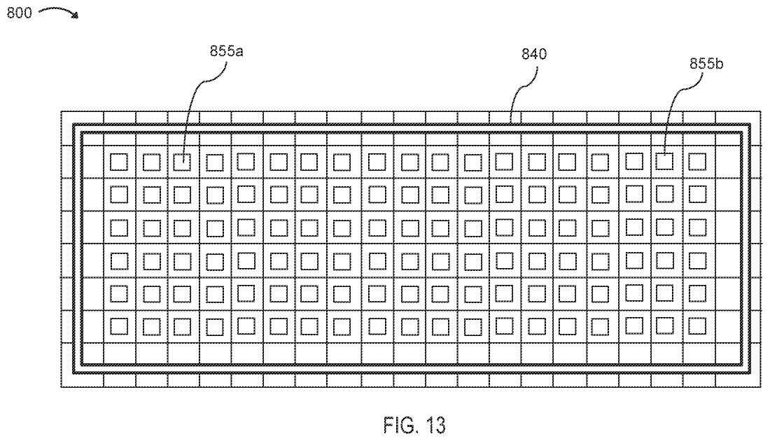

FIG. 13 shows a top plan view of a uLED monolithic array 800 comprising a plurality of pixels arranged in a grid of 6×19. Pixels 855a and 855b are examples. In this embodiment, a common cathode 840 is connected to the pixels. Anodes, not shown, present on the underside are included with each pixel. In one or more embodiments, the array comprises an arrangement of 2×2 mesas, 4×4 mesas, 20×20 mesas, 50×50 mesas, 100×100 mesas, or n1×n2 mesas, where each of n1 and n2 is a number in a range of from 2 to 1000, and n1 and n2 can be equal or not equal.

In one or more embodiments, arrays of micro-LEDs (uLEDs or uLEDs) are used. Micro-LEDs can support high density pixels having a lateral dimension less than 100 μm by 100 μm. In some embodiments, micro-LEDs with dimensions of about 50 μm in diameter or width and smaller can be used. Such micro-LEDs can be used for the manufacture of color displays by aligning in close proximity micro-LEDs comprising red, blue and green wavelengths.

In some embodiments, the light emitting arrays include small numbers of micro-LEDs positioned on substrates that are centimeter scale area or greater. In some embodiments, the light emitting arrays include micro-LED pixel arrays with hundreds, thousands, or millions of light emitting LEDs positioned together on centimeter scale area substrates or smaller. In some embodiments, micro-LEDs can include light emitting diodes sized between 30 microns and 500 microns. The light emitting array(s) can be monochromatic, RGB, or other desired chromaticity. In some embodiments, pixels can be square, rectangular, hexagonal, or have curved perimeter. Pixels can be of the same size, of differing sizes, or similarly sized and grouped to present larger effective pixel size.

In some embodiments, light emitting pixels and circuitry supporting light emitting arrays are packaged and optionally include a submount or printed circuit board connected for powering and controlling light production by semiconductor LEDs. In certain embodiments, a printed circuit board supporting light emitting array includes electrical vias, heat sinks, ground planes, electrical traces, and flip chip or other mounting systems. The submount or printed circuit board may be formed of any suitable material, such as ceramic, silicon, aluminum, etc. If the submount material is conductive, an insulating layer is formed over the substrate material, and the metal electrode pattern is formed over the insulating layer. The submount can act as a mechanical support, providing an electrical interface between electrodes on the light emitting array and a power supply, and also provide heat sink functionality.

In some embodiments, LED light emitting arrays include optical elements such as lenses, metalenses, and/or pre-collimators. Optical elements can also or alternatively include apertures, filters, a Fresnel lens, a convex lens, a concave lens, or any other suitable optical element that affects the projected light from the light emitting array. Additionally, one or more of the optical elements can have one or more coatings, including UV blocking or anti-reflective coatings. In some embodiments, optics can be used to correct or minimize two- or three dimensional optical errors including pincushion distortion, barrel distortion, longitudinal chromatic aberration, spherical aberration, chromatic aberration, field curvature, astigmatism, or any other type of optical error. In some embodiments, optical elements can be used to magnify and/or correct images. Advantageously, in some embodiments magnification of display images allows the light emitting array to be physically smaller, of less weight, and require less power than larger displays. Additionally, magnification can increase a field of view of the displayed content allowing display presentation equals a user's normal field of view.

### Applications

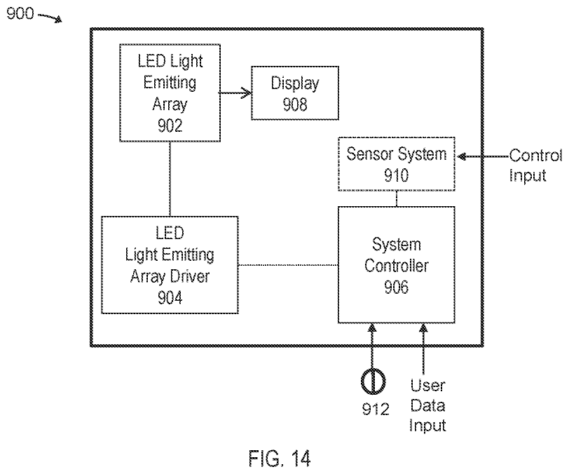

FIG. 14 schematically illustrates an exemplary display system 900 utilizing LEDs, including uLEDs, disclosed herein. The display system 900 comprises an LED light emitting array 902 and display 908 in electrical communication with an LED driver 904. The display system 900 also comprises a system controller 906, such as a microprocessor. The controller 906 is coupled to the LED driver 904. The controller 906 may also be coupled to the display 908 and to optional sensor(s) 910, and be powered by power source 912. In one or more embodiments, user data input is provided to system controller 906.

In one or more embodiments, the system is a camera flash system utilizing uLEDs. In such an embodiment, the LED light emitting array 902 is an illumination array and lens system and the display 908 comprises a camera, wherein the LEDs of 902 and the camera of 908 may be controlled by the controller 906 to match their fields of view.

Optionally sensors 910 with control input may include, for example, positional sensors (e.g., a gyroscope and/or accelerometer) and/or other sensors that may be used to determine the position, speed, and orientation of system. The signals from the sensors 910 may be supplied to the controller 906 to be used to determine the appropriate course of action of the controller 906 (e.g., which LEDs are currently illuminating a target and which LEDs will be illuminating the target a predetermined amount of time later).

In operation, illumination from some or all of the pixels of the LED array in 902 may be adjusted-deactivated, operated at full intensity, or operated at an intermediate intensity. As noted above, beam focus or steering of light emitted by the LED array in 902 can be performed electronically by activating one or more subsets of the pixels, to permit dynamic adjustment of the beam shape without moving optics or changing the focus of the lens in the lighting apparatus.

LED array systems such as described herein may support various other beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. The light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting.

Other applications of LED devices herein include an augmented reality/virtual reality (AR/VR) systems, which may utilize uLEDs disclosed herein. One or more AR/VR systems include: augmented (AR) or virtual reality (VR) headsets, glasses, or projectors. Such AR/VR systems includes an LED light emitting array, an LED driver (or light emitting array controller), a system controller, an AR or VR display, a sensor system 810. Control input may be provided to the sensor system, while power and user data input is provided to the system controller. As will be understood, in some embodiments modules included in the AR/VR system can be compactly arranged in a single structure, or one or more elements can be separately mounted and connected via wireless or wired communication. For example, the light emitting array, AR or VR display, and sensor system can be mounted on a headset or glasses, with the LED driver and/or system controller separately mounted.

In one embodiment, the light emitting array can be used to project light in graphical or object patterns that can support AR/VR systems. In some embodiments, separate light emitting arrays can be used to provide display images, with AR features being provided by a distinct and separate micro-LED array. In some embodiments, a selected group of pixels can be used for displaying content to the user while tracking pixels can be used for providing tracking light used in eye tracking. Content display pixels are designed to emit visible light, with at least some portion of the visible band (approximately 400 nm to 750 nm). In contrast, tracking pixels can emit light in visible band or in the IR band (approximately 750 nm to 2,200 nm), or some combination thereof. As an alternative example, the tracking pixels could operate in the 800 to 1000 nanometer range. In some embodiments, the tracking pixels can emit tracking light during a time period that content pixels are turned off and are not displaying content to the user.

The AR/VR system can incorporate a wide range of optics in the LED light emitting array and/or AR/VR display, for example to couple light emitted by the LED light emitting array into AR/VR display as discussed above. For AR/VR applications, these optics may comprise nanofins and be designed to polarize the light they transmit.

In one embodiment, the light emitting array controller can be used to provide power and real time control for the light emitting array. For example, the light emitting array controller can be able to implement pixel or group pixel level control of amplitude and duty cycle. In some embodiments, the light emitting array controller further includes a frame buffer for holding generated or processed images that can be supplied to the light emitting array. Other supported modules can include digital control interfaces such as Inter-Integrated Circuit (I2C) serial bus, Serial Peripheral Interface (SPI), USB-C, HDMI, Display Port, or other suitable image or control modules that are configured to transmit needed image data, control data or instructions.

In operation, pixels in the images can be used to define response of corresponding light emitting array, with intensity and spatial modulation of LED pixels being based on the image(s). To reduce data rate issues, groups of pixels (e.g. 5×5 blocks) can be controlled as single blocks in some embodiments. In some embodiments, high speed and high data rate operation is supported, with pixel values from successive images able to be loaded as successive frames in an image sequence at a rate between 30 Hz and 100 Hz, with 60 Hz being typical. Pulse width modulation can be used to control each pixel to emit light in a pattern and with an intensity at least partially dependent on the image.

In some embodiments, the sensor system can include external sensors such as cameras, depth sensors, or audio sensors that monitor the environment, and internal sensors such as accelerometers or two or three axis gyroscopes that monitor AR/VR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position. As another example, based on the one or more measurement signals from one or more gyroscope or position sensors that measure translation or rotational movement, an estimated position of AR/VR system relative to an initial position can be determined.

In some embodiments, the system controller uses data from the sensor system to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow.

Based on changes in position, orientation, or movement of the AR/VR system, the system controller can send images or instructions the light emitting array controller. Changes or modification in the images or instructions can also be made by user data input, or automated data input as needed. User data input can include but is not limited to that provided by audio instructions, haptic feedback, eye or pupil positioning, or connected keyboard, mouse, or game controller.

### Embodiments

Various embodiments are listed below. It will be understood that the embodiments listed below may be combined with all aspects and other embodiments in accordance with the scope of the invention.

Embodiment (a). A test apparatus for an array of micro-light emitting diode (uLEDs), the test device comprising: a primary release layer positioned on the array of uLEDs; an N-contact test pad template in contact with N-contacts of the uLEDs and an N-contact testing bus; and a P-contact test pad template in contact with P-contacts of the uLEDs and a P-contact testing bus.

Embodiment (b). The test apparatus of embodiment (a), wherein the N-contacts of the uLEDs are connected in parallel with the N-contact testing bus and/or the P-contacts of the uLEDs are connected in parallel with the P-contact testing bus.

Embodiment (c). The test apparatus of embodiment (a) or (b), wherein the primary release layer comprises a photoresist material.

Embodiment (d). The test apparatus of embodiment (c), wherein the photoresist material comprises polydimethylglutarimide (PMGI) and/or a cyclopentanone-based polymer.

Embodiment (e). The test apparatus of any of embodiments (a) to (d), wherein the uLED array comprises a device substrate comprising a material selected from the group consisting of: a sapphire, silicon carbide, and III-nitride.

Embodiment (f). The test apparatus of embodiments (a) to (e) further comprising an array support.

Embodiment (g). The test apparatus of embodiments (a) to (f), wherein each of the N-contact test pad template and the P-contact test pad template comprises one or more of: copper (Cu), aluminum (Al), nickel (Ni), titanium (Ti), titanium-tungsten (TiW), silver (Ag), gold (Au), platinum (Pt), and palladium (Pd).

Embodiment (h). The test apparatus of embodiments (a) to (g) effective for testing greater than or equal to 10,000 uLEDs at a time.

Embodiment (i). The test apparatus of embodiment (h) effective for testing greater than or equal to 100,000 uLEDs at a time.

Embodiment (j). The test apparatus of embodiment (i) effective for testing greater than or equal to 500,000 uLEDs at a time.

Embodiment (k). A method of manufacturing a light source comprises: testing an array of micro-light emitting diode (uLEDs) with the test apparatus according to any of embodiments (a) to (j); and assembling a light source comprising uLEDs identified as acceptable upon the testing.

Embodiment (l). The method of embodiment (k), wherein the testing comprises: applying power to the test apparatus; detecting light emission from the test apparatus with an optical sensor; and identifying acceptable and/or defective pixels.

Embodiment (m). The method of embodiment (k) or (l) further comprising generating a pixel map of locations of the acceptable and/or defective pixels.

Embodiment (n). The method of embodiment (m) further comprising conducting a pick-and-place operation including only uLEDs comprising the acceptable pixels.

Embodiment (o). A method of manufacturing a test apparatus for testing an array of micro-light emitting diode (uLEDs), the method comprising: depositing a primary release material on the array of uLEDs, each uLED comprising: a pixel, an N-contact, and a P-contact, each of the N-contact and the P-contact in contact with each of the pixels; etching the primary release material to expose each of the N-contacts and the P-contacts, thereby forming a primary release layer; and preparing an N-contact test pad template on each of the N-contacts, an N-contact testing bus in communication with the N-contact test pad template, a P-contact test pad template on each of the P-contacts, and a P-contact testing bus in communication with the P-contact test pad template.

Embodiment (p). The method of embodiment (o), wherein preparing the N-contact test pad template, the N-contact testing bus, the P-contact test pad template, and the P-contact testing bus comprises: depositing a test pad material on the array; and patterning the test pad material.

Embodiment (q). The method of embodiment (o), wherein preparing the N-contact test pad template, the N-contact testing bus, the P-contact test pad template, and the P-contact testing bus comprises: depositing a mask material in a pattern on the array, depositing a test pad material, and removing the mask material.

Embodiment (r). The method of any of embodiments (o) to (q), wherein the N-contacts of the uLEDs are connected in parallel with the N-contact testing bus, and/or the P-contacts of the uLEDs are connected in parallel with the P-contact testing bus.

Embodiment(s). The method of any of embodiments (o) to (r), wherein the primary release layer comprises a photoresist material.

Embodiment (t). The method of embodiment(s), wherein the photoresist material comprises polydimethylglutarimide (PMGI) and/or a cyclopentanone-based polymer.

Embodiment (u). The method of any of embodiments (o) to (t), wherein the N-contact test pad template, the N-contact testing bus, the P-contact test pad template, and the P-contact testing bus comprises one or more of: copper (Cu), aluminum (Al), nickel (Ni), titanium (Ti), titanium-tungsten (TiW), silver (Ag), gold (Au), platinum (Pt), and palladium (Pd).

Embodiment (v). Any of the embodiments (a) to (u), wherein the uLEDs are integral to a monolithic body.

Embodiment (w). Any of the embodiments (a) to (v), wherein the uLED array comprises a device substrate comprising a material selected from the group consisting of: a sapphire, silicon carbide, and III-nitride.

Embodiment (x). Any of the embodiments (a) to (w), wherein each uLED has at least one characteristic dimension of greater than or equal to 1 micrometer less than or equal to 300 micrometers, the characteristic dimension being selected from the group consisting of: height, width, depth, thickness, and combinations thereof.

Embodiment (y). Any of the embodiments (a) to (x), wherein for each uLED a p-contact and an n-contact are formed on a same side of pixel.

Embodiment (z). Any of the embodiments (a) to (y), wherein each pixel comprises a stack of semiconductor layers including an active region.

Embodiment (aa). Any of the embodiments (a) to (z), wherein the test apparatus further comprises an array support that is a complementary metal oxide semiconductor (CMOS) integrated circuit (IC) array. In one or more embodiments, the CMOS has metal interconnect bonding corresponding to the N- and P-contacts of the uLED array.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

What is claimed is:

1. A test apparatus for an array of micro-light emitting diode (uLEDs), the test device comprising:
a primary release layer positioned on the array of uLEDs;
an N-contact test pad template in contact with N-contacts of the uLEDs and an N-contact testing bus; and
a P-contact test pad template in contact with P-contacts of the uLEDs and a P-contact testing bus.

2. The test apparatus of claim 1, wherein the N-contacts of the uLEDs are connected in parallel with the N-contact testing bus and/or the P-contacts of the uLEDs are connected in parallel with the P-contact testing bus.

3. The test apparatus of claim 1, wherein the primary release layer comprises a photoresist material.

4. The test apparatus of claim 3, wherein the photoresist material comprises polydimethylglutarimide (PMGI) and/or a cyclopentanone-based polymer.

5. The test apparatus of claim 1, wherein the uLED array comprises a device substrate comprising a material selected from the group consisting of: a sapphire, silicon carbide, and III-nitride.

6. The test apparatus of claim 1 further comprising an array support.

7. The test apparatus of claim 1, wherein each of the N-contact test pad template and the P-contact test pad template comprises one or more of: copper (Cu), aluminum (Al), nickel (Ni), titanium (Ti), titanium-tungsten (TiW), silver (Ag), gold (Au), platinum (Pt), and palladium (Pd).

8. The test apparatus of claim 1 effective for testing greater than or equal to 10,000 uLEDs at a time.

9. The test apparatus of claim 8 effective for testing greater than or equal to 100,000 uLEDs at a time.

10. The test apparatus of claim 9 effective for testing greater than or equal to 500,000 uLEDs at a time.

11. A method of manufacturing a light source comprises:
testing an array of micro-light emitting diode (uLEDs) with the test apparatus according to claim 1; and
assembling a light source comprising uLEDs identified as acceptable upon the testing.

12. The method of claim 11, wherein the testing comprises:
applying power to the test apparatus;
detecting light emission from the test apparatus with an optical sensor; and
identifying acceptable and/or defective pixels.

13. The method of claim 11 further comprising generating a pixel map of locations of the acceptable and/or defective pixels.

14. The method of claim 13 further comprising conducting a pick-and-place operation including only uLEDs comprising the acceptable pixels.

15. A method of manufacturing a test apparatus for testing an array of micro-light emitting diode (uLEDs), the method comprising:
depositing a primary release material on the array of uLEDs, each uLED comprising: a pixel, an N-contact, and a P-contact, each of the N-contact and the P-contact in contact with each of the pixels;
etching the primary release material to expose each of the N-contacts and the P-contacts, thereby forming a primary release layer; and
preparing an N-contact test pad template on each of the N-contacts, an N-contact testing bus in communication with the N-contact test pad template, a P-contact test pad template on each of the P-contacts, and a P-contact testing bus in communication with the P-contact test pad template.

16. The method of claim 15, wherein preparing the N-contact test pad template, the N-contact testing bus, the P-contact test pad template, and the P-contact testing bus comprises: depositing a test pad material on the array; and patterning the test pad material.

17. The method of claim 15, wherein preparing the N-contact test pad template, the N-contact testing bus, the P-contact test pad template, and the P-contact testing bus comprises: depositing a mask material in a pattern on the array, depositing a test pad material, and removing the mask material.

18. The method of claim 15, wherein the N-contacts of the uLEDs are connected in parallel with the N-contact testing bus, and/or the P-contacts of the uLEDs are connected in parallel with the P-contact testing bus.

19. The method of claim 15, wherein the primary release layer comprises a photoresist material.

20. The method of claim 15, wherein the N-contact test pad template, the N-contact testing bus, the P-contact test pad template, and the P-contact testing bus comprises one or more of: copper (Cu), aluminum (Al), nickel (Ni), titanium (Ti), titanium-tungsten (TiW), silver (Ag), gold (Au), platinum (Pt), and palladium (Pd).
